(19) United States
(12) Patent Application Publication
(10) Pub. No.: US 2025/0031461 A1
(43) Pub. Date: Jan. 23, 2025

(54) SURFACE MODIFICATION METHOD FOR REDUCING WAFER DEFECTS

(71) Applicant: Shanghai Huali Integrated Circuit Corporation, Shanghai (CN)

(72) Inventor: Jin Chen, Shanghai (CN)

(73) Assignee: Shanghai Huali Integrated Circuit Corporation, Shanghai (CN)

(21) Appl. No.: 18/738,394

(22) Filed: Jun. 10, 2024

(30) Foreign Application Priority Data
Jul. 19, 2023 (CN) 202310890183.8

(51) Int. Cl. H01L 27/146; H01L 21/66

(52) U.S. Cl. CPC H01L 27/14687; H01L 22/20

(57) ABSTRACT

The present disclosure provides a surface modification method for reducing wafer defects, including: providing a wafer, and performing a first time wet etching for a silicon surface of the wafer; performing an oxidization treatment for the silicon surface of the wafer to reduce surface roughness, and then cleaning the silicon surface using a cleaning solution, so as to remove possible particle contamination resulting from a previous process; and performing a second time wet etching for the silicon surface of the wafer. In a wafer thinning process applied in the present disclosure, the oxidation treatment for the silicon surface of the wafer is inserted between two times of wet etching for the silicon surface of the wafer, so as to reduce the roughness of the silicon surface of the wafer and improve the thickness uniformity of the wafer after the thinning, thereby effectively reducing surface defects.

### CROSS-REFERENCE TO RELATED APPLICATIONS

This application claims priority to Chinese patent application No. 202310890183.8, filed on Jul. 19, 2023, the disclosure of which is incorporated herein by reference in its entirety.

### TECHNICAL FIELD

The present disclosure relates to the technical field of semiconductors, and in particular to a surface modification method for reducing wafer defects.

### BACKGROUND

The last step of the back-side illumination (BSI) thinning process in an image sensor manufacturing process requires the use of a tetramethylammonium hydroxide (TMAH) solution to etch the epitaxy silicon layer (EPI Si) to a target thickness. Different products are provided with different target thicknesses, which usually fall within the range of 2-7 μm. The requirement for wafer thickness is quite strict. The average thickness of each wafer varies from wafer to wafer in a range of less than 0.06 μm, and the total thickness variation within a wafer is less than 0.18 μm.

In order to reduce the impact on process variation from uneven silicon wafer thickness resulting from silicon chemical-mechanical polishing, auto process control (APC) technique is applied during TMAH etch to manage the process. Even though the regular temperature of TMAH in the tank is strictly controlled, the real temperature of TMAH that actually reaches the surface of the wafer in each operating chamber is still uncontrollable. So the etch rate of TMAH for the epitaxy (EPI) Si is affected by the process temperature and oxygen concentration. In addition, the TMAH exchange period is generally controlled to occur within 6 hours, the etch rate difference between the initial and terminal stages of the TMAH exchange period results in significant fluctuation of the average thickness from wafer to wafer in practice.

### BRIEF SUMMARY

The present disclosure provides a surface modification method to reduce wafer defects, and solve the problem of an uneven wafer thickness due to an etch rate difference during a wafer thinning process.

The present surface modification method includes:
step I, providing a wafer, and performing a first time wet etching on the silicon surface of the wafer;
step II, performing an oxidization treatment for the silicon surface of the wafer to reduce surface roughness, and then cleaning the silicon surface using a cleaning solution, to remove possible particle contamination from previous processes; and
step III, performing a second time wet etching on the silicon surface of the wafer.

In some examples, an etchant for the first time wet etching in step I is tetramethylammonium hydroxide.

In some examples, an auto process control system is applied in step I to monitor the thickness of an epitaxial layer of the wafer before the first time wet etching.

In some examples, the oxidization treatment for the silicon surface of the wafer is performed using ozone (O₃) in step II to reduce the surface roughness.

In some examples, the concentration of O₃ in step II is at a ppm level; and it takes no more than 1 minute to perform the oxidation treatment.

In some examples, the cleaning solution in step II is SCl (ammonia hydroxide-hydrogen peroxide water mixture).

In some examples, it takes no more than 1 minute to clean the silicon surface in step II.

In some examples, an etchant for the second time wet etching in step III is tetramethylammonium hydroxide.

In some examples, an auto process control system is applied in step III to monitor the thickness of an epitaxial layer on the wafer before the second time wet etching.

As stated above, the surface modification method for reducing wafer defects of the preset disclosure has the following beneficial effects: in a wafer thinning process described in the present disclosure, the oxidation treatment for the silicon surface of the wafer is inserted between the two wet etchings on the silicon surface of the wafer, so as to reduce the roughness of the silicon surface of the wafer and improve the thickness uniformity of the wafer after the thinning process, thereby effectively reducing surface defects.

### BRIEF DESCRIPTION OF THE DRAWINGS

FIG. 1 illustrates a flowchart of the surface modification method for reducing wafer defects according to the preset disclosure;

FIG. 2 shows defect distribution data on the wafer surface after an existing thinning process; and

FIG. 3 shows defect distribution data on the wafer surface after the step III is performed according to the preset disclosure.

### DETAILED DESCRIPTION OF THE DISCLOSURE

The embodiments of the present disclosure are described below using specific examples, and those skilled in the art could readily understand other advantages and effects of the present disclosure from the contents disclosed in the description. The present disclosure can also be implemented or applied using other different specific implementations, and various details in the description can also be modified or changed based on different viewpoints and disclosures without departing from the spirit of the present disclosure.

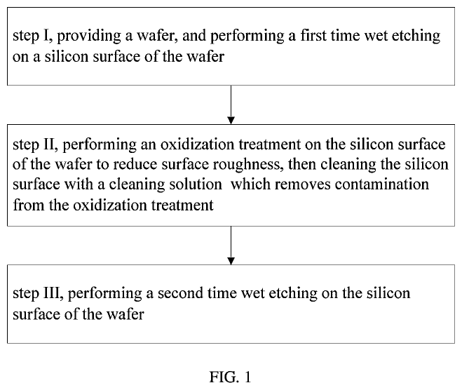

References are made to FIGS. 1 to 3. It should be noted that the drawings provided in the embodiments are only used to illustrate the basic concept of the present disclosure in a schematic way, so the drawings only show the components related to the present disclosure rather than being drawn according to the number, shape, and size of the components in actual implementations. The type, number, and proportion of various components can be changed randomly in the actual implementations, and the layout of the components may be more complicated.

The preset disclosure provides a surface modification method for reducing wafer defects. Referring to FIG. 1, FIG. 1 illustrates a flowchart of the surface modification method for reducing wafer defects according to the preset disclosure. The method at least includes the following steps.
Step I. Provide a wafer, and perform a first time wet etching for a silicon surface of the wafer.

Furthermore, in this embodiment of the present disclosure, an etchant for the first time wet etching in step I is tetramethylammonium hydroxide (TMAH). In step I, the first time wet etching is first performed for the silicon surface of the wafer to be waited a back-side illumination (BSI) thinning process.

Furthermore, in this embodiment of the present disclosure, an auto process control system is applied in step I to monitor the thickness of an epitaxial layer of the wafer before the first time wet etching. In the present disclosure, the silicon surface of the wafer is the surface of the epitaxial layer.
Step II. Perform an oxidization treatment for the silicon surface of the wafer to reduce surface roughness, and then clean the silicon surface using a cleaning solution, so as to remove possible particle contamination resulting from a previous process.

Furthermore, in this embodiment of the present disclosure, the oxidization treatment for the silicon surface of the wafer is performed using O₃ in step II to reduce the surface roughness.

Furthermore, in this embodiment of the present disclosure, the concentration of O₃ in step II is at a ppm level; and a time of the oxidation treatment is no more than 1 min.

Furthermore, in this embodiment of the present disclosure, the cleaning solution in step II is SCl.

Furthermore, in this embodiment of the present disclosure, a time for cleaning the silicon surface in step II is no more than 1 min.

In step II, the oxidization treatment for the silicon surface of the wafer is performed to reduce the surface roughness. The oxidization treatment for the silicon surface is performed after the first time wet etching for the silicon surface in step I. In this embodiment, ozone (O₃) is applied to perform the oxidization treatment for the silicon surface, and the roughness of the oxidized silicon surface is reduced. In this embodiment, the concentration of ozone in this step is at the ppm level; and duration of the oxidation is no more than 1 min.

After the oxidization treatment, the silicon surface is then cleaned using the cleaning solution (SCl), so as to remove the possible particle contamination resulting from the previous process. That is, the silicon surface subjected to the oxidation treatment is cleaned, and a cleaning chemical in this embodiment is the cleaning solution, i.e., SCl, which is a general chemical in the industry.
Step III. Perform a second time wet etching for the silicon surface of the wafer.

Furthermore, in this embodiment of the present disclosure, an etchant for the second time wet etching in step III is tetramethylammonium hydroxide.

Furthermore, in this embodiment of the present disclosure, an auto process control system is applied in step III to monitor the thickness of the epitaxial layer of the wafer before the second time wet etching.

In step III, the second time wet etching is performed for the cleaned silicon surface of the wafer. In this embodiment, the auto process control (APC) system is applied during the second time wet etching to monitor the thickness of the epitaxial layer of the wafer before the second time wet etching. The etchant for the second time wet etching is tetramethylammonium hydroxide. The thicknesses of pre- and post-etching can be controlled by monitoring the thickness of the epitaxial layer prior to two times of wet etching.

The wafer is thinned after the two times of wet etching, and the oxidation of the silicon surface is applied between the two thinning processes, resulting in a reduction of the roughness of the silicon surface. Meanwhile, the cleaning is performed to remove the contamination resulting from the previous process. As such, the risk of defects occurring on the wafer surface in subsequent processes is further reduced.

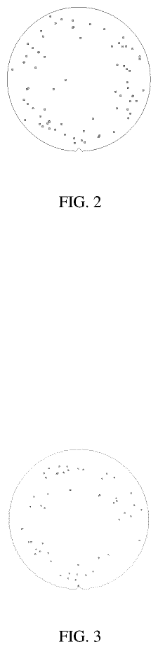

Referring to FIG. 2, FIG. 2 shows defect distribution data on the wafer surface after an existing thinning process. FIG. 3 shows defect distribution data on the wafer surface after step III is performed according to the preset disclosure. Upon comparison, it is found that the number of defects in FIG. 2 is significantly larger than the number of defects in FIG. 3, which confirms that the method of the present disclosure is significantly effective in reducing the defects on the wafer surface. To sum up, in a wafer thinning process applied in the present disclosure, the oxidation treatment for the silicon surface of the wafer is inserted between two wet etchings for the silicon surface of the wafer, so as to reduce the roughness of the silicon surface of the wafer and improve the thickness uniformity of the wafer after the thinning process, thereby effectively reducing surface defects. Therefore, the present disclosure has effectively overcome various shortcomings of the existing techniques, thus has high industrial utilization value.

The above embodiments merely illustrate the principle and effect of the present disclosure, rather than limiting the present disclosure. Any person skilled in the art can modify or change the above embodiments without departing from the spirit and scope of the present disclosure. Therefore, all equivalent modifications or changes made by those with ordinary skill in the art without departing from the spirit and technical idea disclosed in the present disclosure shall still be covered by the claims of the present disclosure.

What is claimed is:

1. A surface modification method for reducing wafer defects, at least comprising:
step I, providing a wafer, and performing a first time wet etching on a silicon surface of the wafer;
step II, performing an oxidization treatment on the silicon surface of the wafer to reduce surface roughness, then cleaning the silicon surface with a cleaning solution which removes contamination from the oxidization treatment; and
step III, performing a second time wet etching on the silicon surface of the wafer.

2. The surface modification method for reducing wafer defects according to claim 1, wherein an etchant for the first time wet etching in step I is tetramethylammonium hydroxide.

3. The surface modification method for reducing wafer defects according to claim 1, wherein an auto process control system is applied in step I to monitor a thickness of an epitaxial layer on the wafer before the first time wet etching.

4. The surface modification method for reducing wafer defects according to claim 1, wherein the oxidization treatment on the silicon surface of the wafer to reduce the surface roughness is performed with ozone (O₃) in step II.

5. The surface modification method for reducing wafer defects according to claim 1, wherein a concentration of O₃ in step II is at a ppm level; and a duration of the oxidation treatment is no more than 1 minute.

6. The surface modification method for reducing wafer defects according to claim 1, wherein the cleaning solution in step II is SCl.

7. The surface modification method for reducing wafer defects according to claim 6, wherein a duration for the cleaning the silicon surface in step II is no more than 1 minute.

8. The surface modification method for reducing wafer defects according to claim 1, wherein an etchant for the second time wet etching in step III is tetramethylammonium hydroxide.

9. The surface modification method for reducing wafer defects according to claim 1, wherein an auto process control system is applied in step III to monitor a thickness of an epitaxial layer on the wafer before the second time wet etching.
